(19) United States
(12) Patent Application Publication
(10) Pub. No.: US 2023/0098338 A1
(43) Pub. Date: Mar. 30, 2023

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Inkeol PARK, Suwon-si (KR); Beomjun JOO, Suwon-si (KR)

(21) Appl. No.: 17/942,394

(22) Filed: Sep. 12, 2022

(30) Foreign Application Priority Data
Sep. 15, 2021 (KR) 10-2021-0123393

(51) Int. Cl. G03F 7/11; G03F 7/16; C09D 4/00

(52) U.S. Cl. CPC G03F 7/11; G03F 7/168; C09D 4/00

(57) ABSTRACT

A hardmask composition, a hardmask layer including a cured product of the hardmask composition, and a method of forming patterns from the hardmask composition, the hardmask composition includes a compound represented by Chemical Formula 1, and a solvent,

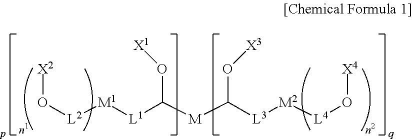

### CROSS-REFERENCE TO RELATED APPLICATION

This application claims priority to and the benefit of Korean Patent Application No. 10-2021-0123393 filed in the Korean Intellectual Property Office on Sep. 15, 2021, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may use effective lithographic techniques.

Some lithographic techniques include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a compound represented by Chemical Formula 1, and a solvent,

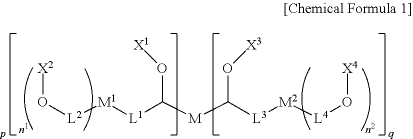

wherein, in Chemical Formula 1, M includes a condensed ring structure including two or more benzene rings, M¹ and M² are each independently a substituted or unsubstituted C6 to C20 aromatic hydrocarbon group, X¹ to X⁴ are each independently hydrogen, a substituted or unsubstituted C1 to C30 saturated aliphatic hydrocarbon group, a substituted or unsubstituted C2 to C30 unsaturated aliphatic hydrocarbon group, a substituted or unsubstituted C3 to C30 saturated or unsaturated alicyclic hydrocarbon group, or a combination thereof, provided that at least one of X¹ to X⁴ is a substituted or unsubstituted C2 to C30 unsaturated aliphatic hydrocarbon group or a substituted or unsubstituted C3 to C30 unsaturated alicyclic hydrocarbon group, L¹ to L⁴ are each independently a single bond, a substituted or unsubstituted divalent C1 to C30 saturated aliphatic hydrocarbon group, a substituted or unsubstituted divalent C2 to C30 unsaturated aliphatic hydrocarbon group, or a combination thereof, n¹ and n² are each independently an integer greater than or equal to 0, provided that n¹ does not exceed a valence of M¹ and that n² does not exceed a valence of M², and p and q are each independently an integer greater than or equal to 0, and p+q is greater than or equal to 1, provided that p+q does not exceed a valence of M.

The embodiments may be realized by providing a hardmask layer comprising a cured product of the hardmask composition according to an embodiment.

The embodiments may be realized by providing a method of forming patterns, the method including providing a material layer on a substrate, applying the hardmask composition according to an embodiment on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed portion of the material layer.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not an exclusive term, e.g., “A or B” would include A, B, or A and B.

As used herein, when a definition is not otherwise provided, ‘substituted’ may refer to replacement of a hydrogen atom of a compound by a substituent selected from a halogen atom (F, Br, C1, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, adjacent two substituents of the halogen atom (F, Br, C1, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring. For example, the substituted C6 to C30 aryl group may be fused with another adjacent substituted C6 to C30 aryl group to form a substituted or unsubstituted fluorene ring.

As used herein, when a definition is not otherwise provided, “hetero” may refer to one including 1 to 3 heteroatoms selected from N, O, S, Se, and P. “Heterocyclic group” has a concept including a heteroaryl group, and may contain at least one hetero atom selected from N, O, S, P, and Si instead of carbon (C) in a ring compound such as an aryl group, a cycloalkyl group, a fused ring thereof, or a combination thereof. When the heterocyclic group is a fused ring, the entire heterocyclic group or each ring may include one or more heteroatoms.

As used herein, when a definition is not otherwise provided, “saturated aliphatic hydrocarbon group” includes a functional group in which all bonds between carbons are single bonds, for example, an alkyl group or an alkylene group.

As used herein, when a definition is not otherwise provided, “unsaturated aliphatic hydrocarbon group” refers to a functional group in which an intercarbon bond includes one or more unsaturated bonds, and may include, for example, a double bond or a triple bond, for example, an alkenyl group, an alkynyl group, an alkenylene group, or an alkynylene group.

As used herein, when a definition is not otherwise provided, “saturated alicyclic hydrocarbon group” refers to a cyclic functional group in which all carbon-carbon bonds are single bonds, for example, a cycloalkylene group.

As used herein, when a definition is not otherwise provided, “unsaturated alicyclic hydrocarbon group” includes a cyclic functional group in which a carbon-carbon bond includes one or more unsaturated bonds, for example, a cycloalkenylene group or a cycloalkynylene group.

As used herein, when a definition is not otherwise provided, “aromatic hydrocarbon group” refers to a group having one or more hydrocarbon aromatic moieties, in which hydrocarbon aromatic moieties are linked by a single bond and hydrocarbon aromatic moieties are directly or indirectly fused with non-aromatic fused rings. More specifically, the substituted or unsubstituted aromatic hydrocarbon group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups, but is not limited thereto.

As used herein, when specific definition is not otherwise provided, “combination” refers to mixing or copolymerization.

As used herein, when specific definition is not otherwise provided, “molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

There is a constant trend in the semiconductor industry to reduce a size of chips, and in order to meet this demand, a line width of a resist should be patterned to have several tens of nanometers through lithography. Accordingly, a height of the resist may be limited to support the line width of the resist pattern, but the resist may have insufficient resistance in the etching process. In order to compensate for this, an auxiliary layer, which is called a hardmask layer, may be used between a material layer for etching and a photoresist layer.

Some hardmask layers may be formed in a chemical or physical deposition method and may have low economic efficiency due to a large-scale equipment and a high process cost. Therefore, a spin-coating technique for forming a hardmask layer may be, and this could slightly lower the etch resistance of the hardmask layer compared to the case of using the deposition method.

One or more embodiments may provide a hardmask composition having little or no deteriorated solubility in a solvent used in semiconductors as well as high etching properties and heat resistance. In an implementation, a core of a compound included in the composition may include a ring in which two or more benzene rings are condensed, and a carbon content of a substituent on the core may be increased. Thus, a hardmask composition may have an overall increased carbon content without deteriorating solubility in a solvent, and a hardmask layer formed of the hardmask composition may have high etch resistance and excellent heat resistance.

A hardmask composition according to an embodiment may include, e.g., a compound represented by Chemical Formula 1, and a solvent.

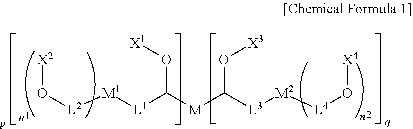

In Chemical Formula 1, M may include, e.g., a condensed ring structure including two or more benzene rings.

M¹ and M² may each independently be or include, e.g., a substituted or unsubstituted C6 to C20 aromatic hydrocarbon group.

X¹ to X⁴ may each independently be or include, e.g., hydrogen, a substituted or unsubstituted C1 to C30 saturated aliphatic hydrocarbon group, a substituted or unsubstituted C2 to C30 unsaturated aliphatic hydrocarbon group, a substituted or unsubstituted C3 to C30 saturated or unsaturated alicyclic hydrocarbon group, or a combination thereof. In an implementation, at least one of X¹ to X⁴ may be, e.g., a substituted or unsubstituted C2 to C30 unsaturated aliphatic hydrocarbon group or a substituted or unsubstituted C3 to C30 unsaturated alicyclic hydrocarbon group,

L¹ to L⁴ may each independently be or include, e.g., a single bond, a substituted or unsubstituted divalent C1 to C30 saturated aliphatic hydrocarbon group, a substituted or unsubstituted divalent C2 to C30 unsaturated aliphatic hydrocarbon group, or a combination thereof.

n¹ and n² may each independently be, e.g., an integer greater than or equal to 0. In an implementation, n1 may not exceed a valence of M¹, and n2 may not exceed a valence of M².

p and q may each independently be, e.g., an integer greater than or equal to 0. p+q may be, e.g., greater than or equal to 1. In an implementation, p+q may not exceed a valence of M.

As described above, M in Chemical Formula 1 may include, e.g., a condensed ring including two or more benzene rings as a central core, and a hardmask layer formed of a hardmask composition including the same may have rigid characteristics.

In addition, as described above, when X¹ to X⁴ of Chemical Formula 1 has an organic group including carbon, e.g., is a group other than a hydrogen, a carbon content of the compound may be overall increased, resultantly increasing strength and density of a hardmask layer formed of a composition including such a compound. Accordingly, when a hardmask layer formed of the composition is included, a fine pattern may be easier to form on a material layer to be etched.

In an implementation, when one of X¹ to X⁴ of Chemical Formula 1 is a substituted or unsubstituted C1 to C30 saturated aliphatic hydrocarbon group, a hardmask composition including the same may have excellent solubility in a solvent, and in addition, the composition may be prepared in the form of a solution and thus easily formed into a hardmask layer.

In an implementation, when one of X¹ to X⁴ of Chemical Formula 1 is a substituted or unsubstituted C2 to C30 unsaturated aliphatic hydrocarbon group, the compound may not only have excellent solubility but may also be cross-linked into a polymer with a high molecular weight in a short time during the heat-treatment of the composition into a hardmask layer, and accordingly, the hardmask layer may have a more dense structure and thus excellent etch resistance, mechanical characteristics, heat resistance, and chemical resistance.

In an implementation, M in Chemical Formula 1 may include a condensed ring structure (e.g., moiety) including two or more benzene rings of Group 1.

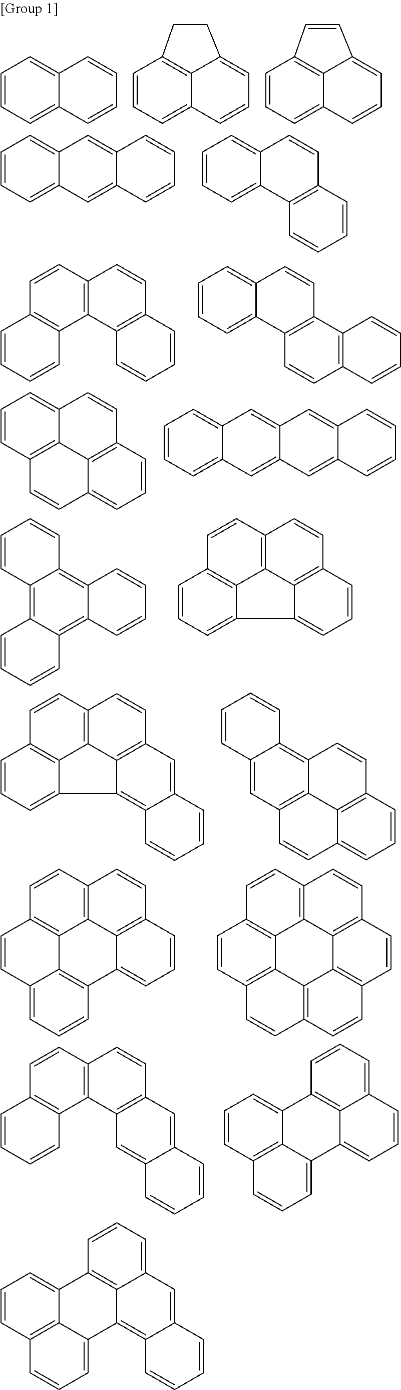

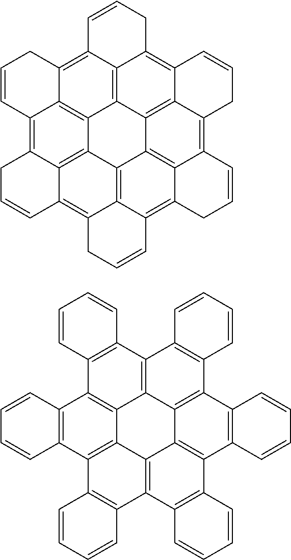

In an implementation, M may include, e.g., a condensed ring structure of Group

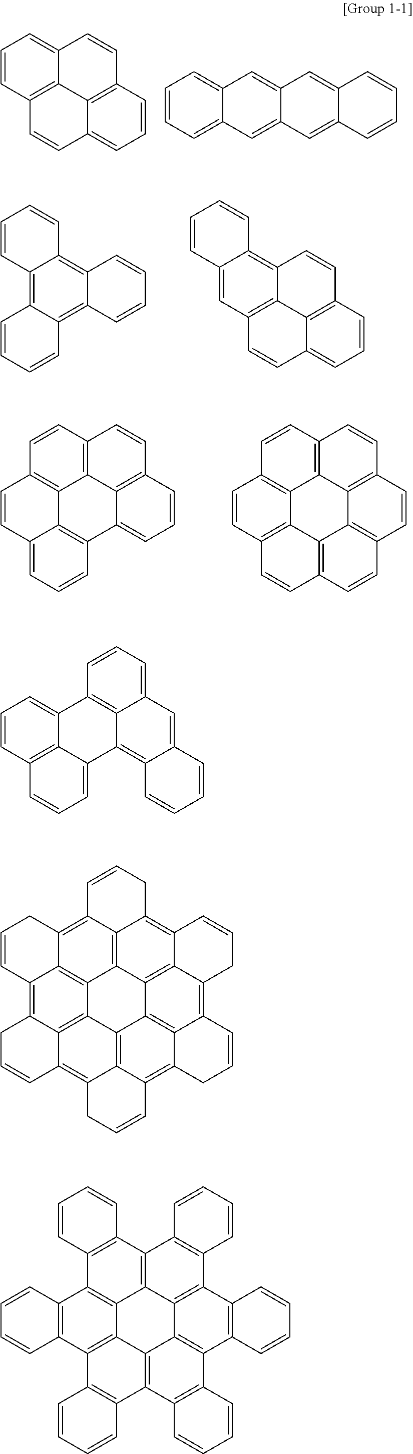

In an implementation, M may include, e.g., a condensed ring structure of Group 1-2.

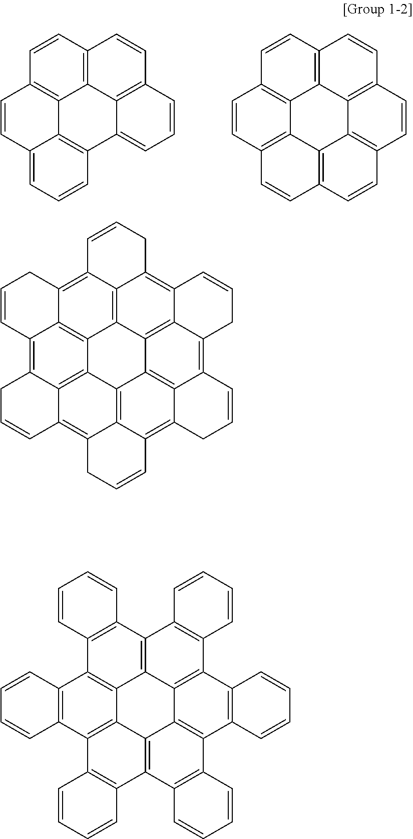

In an implementation, M¹ and M² in Chemical Formula 1 may each independently include, e.g., a substituted or unsubstituted moiety of Group 2 (e.g., as a substituted or unsubstituted C6 to C20 aromatic hydrocarbon).

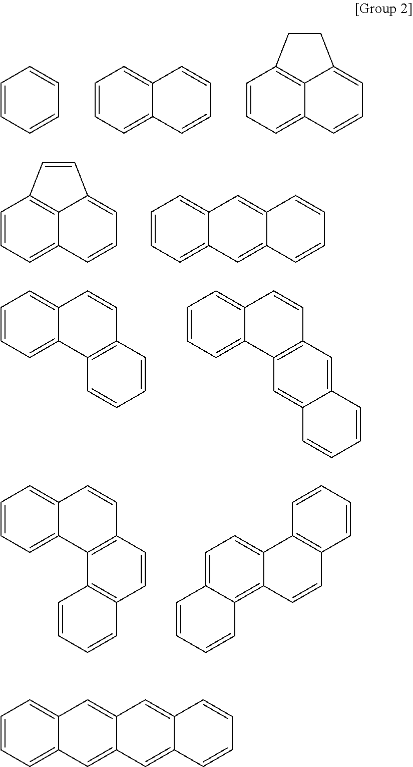

In an implementation, M¹ and M² may each independently be, e.g., a substituted or unsubstituted phenylene group or a substituted or unsubstituted naphthalenylene group.

In an implementation, X¹ to X⁴ in Chemical Formula 1 may each independently be, e.g., hydrogen, a substituted or unsubstituted C1 to C20 alkyl group, a substituted or unsubstituted C2 to C20 alkenyl group, or a substituted or unsubstituted C2 to C20 alkynyl group, or a combination thereof. In an implementation, at least one of X¹ to X⁴ may be, e.g., a substituted or unsubstituted C2 to C20 alkenyl group or a substituted or unsubstituted C2 to C20 alkynyl group. In Chemical Formula 1, X¹ and X³ may be the same as or different from each other, and X² and X⁴ may be the same as or different from each other.

In an implementation, at least one of X¹ to X⁴ may be, e.g., a substituted or unsubstituted C2 to C10 alkenyl group, a C2 to C6 alkenyl group, or a C2 to C4 alkenyl group, or may be, e.g., a substituted or unsubstituted C2 to C10 alkynyl group, a C2 to C6 alkynyl group, or a C2 to C4 alkynyl group.

In an implementation, when any one of X¹ to X⁴ includes a substituted or unsubstituted C1 to C20 alkyl group, it may include, e.g., a methyl group, an ethyl group, a propyl group, a butyl group, a pentyl group, a hexyl group, a heptyl group, or an octyl group. In an implementation, it may include, e.g., a methyl group, an ethyl group, a propyl group, a butyl group, a pentyl group, or a hexyl group.

In an implementation, when any one of X¹ to X⁴ includes a substituted or unsubstituted C2 to C20 alkenyl group, it may include a structure including one or more double bonds, e.g., a vinyl group, a propenyl group, a butenyl group, or a pentenyl group, or a hexenyl group.

In an implementation, when any one of X¹ to X⁴ includes a substituted or unsubstituted C2 to C20 alkynyl group, it may include a structure including one or more triple bonds, e.g., an ethynyl group, a propynyl group, a propargyl group, a butynyl group, a pentynyl group, or a hexynyl group.

In an implementation, L¹ to L⁴ in Chemical Formula 1 may each independently be, e.g., a single bond or a substituted or unsubstituted C1 to C10 alkylene group. In an implementation, it may include, e.g., a single bond, a methylene group, an ethylene group, a propylene group, a butylene group, a pentylene group, or a hexylene group.

In an implementation, n¹ and n² in Chemical Formula 1 may each independently be, e.g., an integer of 0 to 5, an integer of 1 to 3, 1 or 2, or 1.

In an implementation, p and q in Chemical Formula 1 may each independently be, e.g., an integer of 0 or more, an integer of 0 to 5, an integer of 0 to 3, an integer of 0 to 2, or 1. In an implementation, p+q may be an integer of 1 to 10 and may not exceed the valence of M, and may be, e.g., an integer of 1 to 5, an integer of 1 to 3, 1 or 2, or 2.

In an implementation, the compound represented by Chemical Formula 1 may be represented by, e.g., one of Chemical Formula 1-A to Chemical Formula 1-K.

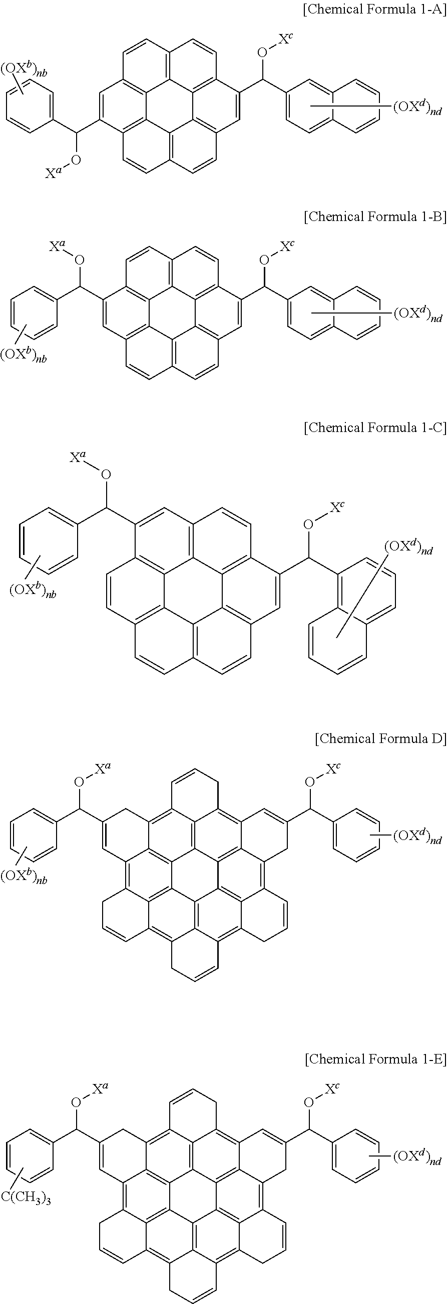

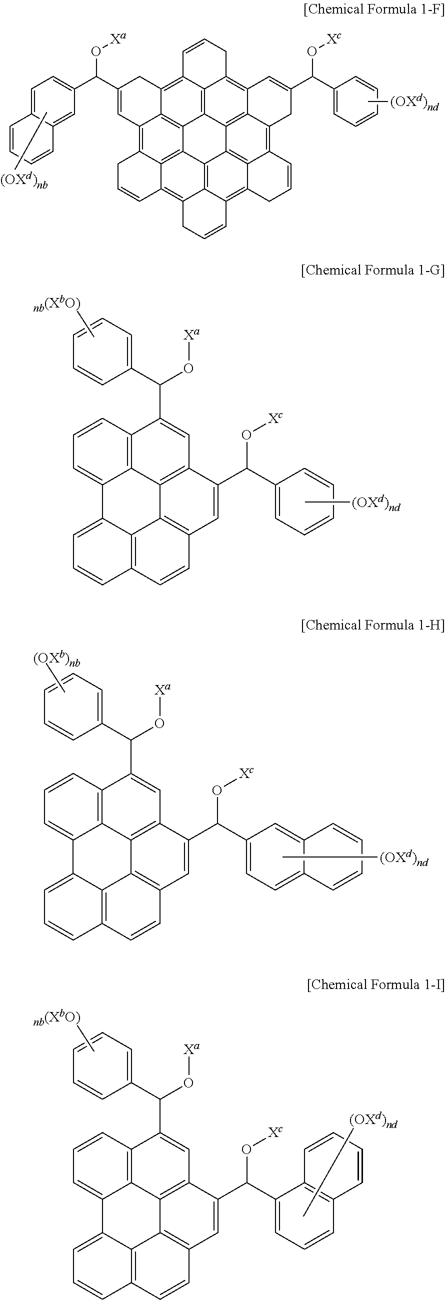

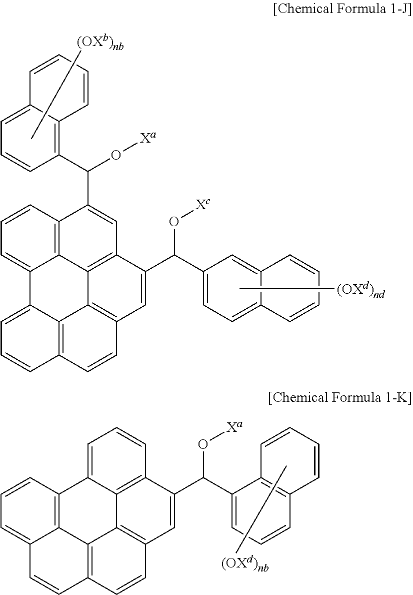

In Chemical Formula 1-A to Chemical Formula 1-K, X^{a} to X^{d} may each independently be, e.g., hydrogen, a substituted or unsubstituted C1 to C20 alkyl group, a substituted or unsubstituted C2 to C20 alkenyl group, a substituted or unsubstituted C2 to C20 alkynyl group, or a combination thereof.

In an implementation, at least one of X^{a} to X^{d} that is present in the compound represented by Chemical Formula 1-A to Chemical Formula 1-K may be a substituted or unsubstituted C2 to C20 alkenyl group or a substituted or unsubstituted C2 to C20 alkynyl group, such that the compound represented by Chemical Formula 1-A to Chemical Formula 1-K may include at least one of a substituted or unsubstituted C2 to C10 alkenyl group or a substituted or unsubstituted C2 to C10 alkynyl group.

nb and nd may each independently be, e.g., an integer of 0 to 3. In an implementation, when both nb and nd are 0, at least one of X^{a} and X^{c} may not be hydrogen.

In an implementation, the compound represented by Chemical Formula 1 may be represented by, e.g., one of Chemical Formula a to Chemical Formula c.

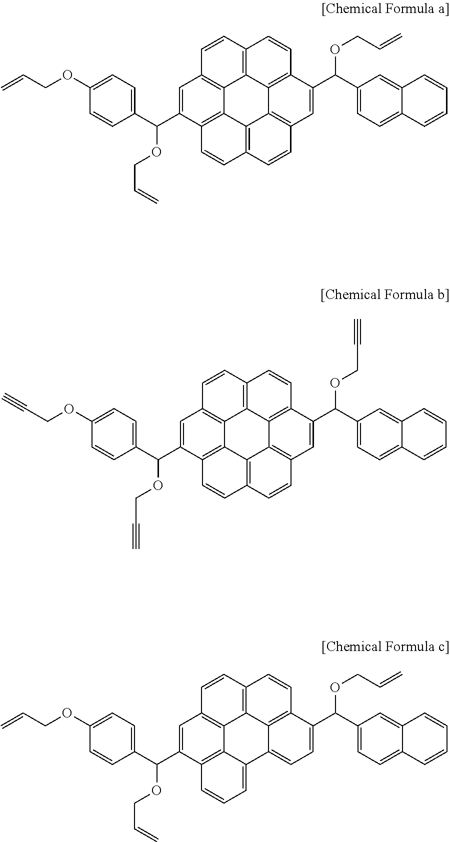 [SMILES: C=CCOc1ccc(C(OCC=C)c2cc3ccc4ccc5c(C(OCC=C)c6ccc7ccccc7c6)cc6ccc7ccc2c2c7c6c5c4c32)cc1 ; C#CCOc1ccc(C(OCC#C)c2cc3ccc4ccc5c(C(OCC#C)c6ccc7ccccc7c6)cc6ccc7ccc2c2c7c6c5c4c32)cc1 ; C=CCOc1ccc(C(OCC=C)c2cc3ccc4ccc5c(C(OCC=C)c6ccc7ccccc7c6)ccc6c7cccc2c7c3c4c56)cc1]

The compound represented by Chemical Formula 1 may have a molecular weight of, e.g., about 200 g/mol to about 3,000 g/mol. In an implementation, the compound may have a molecular weight of, e.g., about 200 g/mol to about 2,500 g/mol, about 200 g/mol to about 2,000 g/mol, about 200 g/mol to about 1,500 g/mol, or about 300 g/mol to about 1,000 g/mol. By having a molecular weight in the above ranges, a carbon content and solubility in a solvent of the hardmask composition including the compound may be adjusted and optimized.

The compound represented by Chemical Formula 1 may be included in the hardmask composition in an amount of about 0.1 wt % to about 30 wt %, based on a total weight of the hardmask composition. In an implementation, the compound may be included in an amount of, e.g., about 0.2 wt % to about 30 wt %, about 0.5 wt % to about 30 wt %, about 1 wt % to about 30 wt %, about 1.5 wt % to about 25 wt %, or about 2 wt % to about 20 wt %. By including the compound within the above ranges, a thickness, a surface roughness, and a planarization degree of the hardmask may be easily adjusted.

The hardmask composition according to an embodiment may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. The solvent may be a suitable solvent having sufficient solubility and/or dispersibility for the compound.

In an implementation, the hardmask composition may further include an additive, e.g., a surfactant, a crosslinking agent, a thermal acid generator, or a plasticizer.

The surfactant may include, e.g., a fluoroalkyl-based compound, an alkylbenzenesulfonate, an alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In addition, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

According to another embodiment, a hardmask layer including a cured product of the aforementioned hardmask composition may be provided.

Hereinafter, a method of forming patterns using the aforementioned hardmask composition is described.

A method of forming patterns according to an embodiment may include providing a material layer on a substrate, applying a hardmask composition including the aforementioned compound and solvent on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching the exposed portion of the material layer.

The substrate may be, e.g., a silicon wafer, a glass substrate, or a polymer substrate.

The material layer may be a material to be finally patterned, e.g., a metal layer such as an aluminum layer and a copper layer, a semiconductor layer such as a silicon layer, or an insulation layer such as a silicon oxide layer and a silicon nitride layer. The material layer may be formed through a method such as a chemical vapor deposition (CVD) process.

The hardmask composition is the same as described above, and may be applied by spin-on coating in a form of a solution. In an implementation, a thickness of the hardmask composition may be, e.g., about 50 Å to about 200,000 Å.

The heat-treating of the hardmask composition may be performed, e.g., at about 100° C. to about 1,000° C. for about 10 seconds to about 1 hour.

In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour and, e.g., the heat-treating may be performed under an atmosphere of air or nitrogen, or an atmosphere having oxygen concentration of 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 100° C. to about 400° C. for about 10 seconds to about 1 hour and, e.g., a second heat-treating process performed at about 100° C. to about 1,000° C., about 300° C. to 1,000° C., about 500° C. to 1,000° C., or about 500° C. to 800° C. for about 10 seconds to about 1 hour consecutively. In an implementation, the first and second heat-treating processes may be performed under an atmosphere of air or nitrogen, or an atmosphere having oxygen concentration of 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include at least one of a first heat-treating process, a second heat-treating process, a UV/Vis curing process, and a near IR curing process, or may include two or more processes consecutively.

In an implementation, the method may further include forming a silicon-containing thin layer on the hardmask layer. The silicon-containing thin layer may be formed of a material, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed portion of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of pattern, and the plurality of pattern may be a metal pattern, a semiconductor pattern, an insulation pattern, and the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### COMPARATIVE SYNTHESIS EXAMPLES

### Comparative Synthesis Example 1

First step: Friedel-Craft Acylation Reaction

50.0 g (0.166 mol) of coronene, 28.4 g (0.166 mol) of 4-methoxybenzoylchloride, 31.6 g (0.166 mol) of 2-naphthoylchloride, and 235 g of 1,2-dichloroethane were put in a flask to prepare a solution. Subsequently, 44.4 g (0.332 mol) of aluminum chloride was slowly added to the solution at ambient temperature and then, heated to 60° C. and stirred for 8 hours. When a reaction was completed, methanol was added to the solution to form precipitates, and the precipitates were filtered, obtaining 4-methoxybenzoyl-2-naphthyl coronene.

Second step: Removal of Methyl Group (Demethylation)

68.2 g (0.115 mol) of the 4-methoxybenzoyl-2-naphthyl coronene obtained in the first step, 58.2 g (0.288 mol) of 1-dodecanethiol, 19.4 g (0.345 mol) of potassium hydroxide, and 191 g of N,N-dimethylformamide were put in a flask and stirred at 120° C. for 8 hours. Subsequently, the mixture was cooled and neutralized to about pH 7 with a 10% hydrogen chloride solution and then, extracted with ethyl acetate, obtaining 4-hydroxy-2-naphthyl benzoyl coronene.

Third step: Reduction Reaction

34.4 g (0.0595 mol) of the 4-hydroxy-2-naphthyl benzoyl coronene obtained in the second step was added to 145 g of tetrahydrofuran in a flask, preparing a solution. 11.3 g (0.297 mol) of a sodium borohydride aqueous solution was slowly added thereto and then, stirred for 24 hours at ambient temperature. When a reaction was completed, the resultant was neutralized to about pH 7 with a 10% hydrogen chloride solution and then, extracted with ethyl acetate, obtaining a compound represented by Chemical Formula 2.

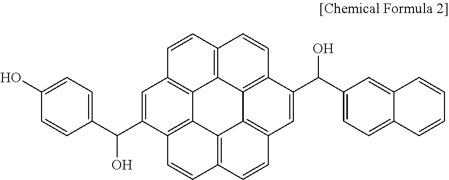 [SMILES: Oc1ccc(C(O)c2cc3ccc4ccc5c(C(O)c6ccc7ccccc7c6)cc6ccc7ccc2c2c7c6c5c4c32)cc1]

### Comparative Synthesis Example 2

First Step: Friedel-Craft Acylation Reaction

50.0 g (0.166 mol) of coronene, 46.8 g (0.333 mol) of benzoyl chloride, and 330 g of 1,2-dichloroethane were put in a flask, preparing a solution. Subsequently, 44.4 g (0.333 mol) of aluminum chloride was slowly added thereto at ambient temperature and then, stirred at 60° C. for 8 hours. When a reaction was completed, methanol was added thereto to form precipitates, and the precipitates were filtered, obtaining double-substituted benzoyl coronene.

Second Step: Reduction Reaction

25.0 g (0.0492 mol) of the double-substituted benzoyl coronene obtained in the first step and 174 g of tetrahydrofuran were put in a flask, preparing a solution. 18.6 g (0.492 mol) of a sodium borohydride aqueous solution was slowly added to the solution and then, stirred at ambient temperature for 24 hours. When a reaction was completed, the resultant was neutralized to pH 7 or so with a 10% hydrogen chloride solution and extracted with ethyl acetate, obtaining a compound represented by Chemical Formula 3.

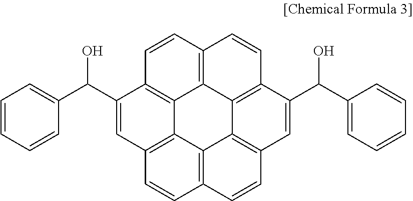 [SMILES: OC(c1ccccc1)c1cc2ccc3ccc4cc(C(O)c5ccccc5)c5ccc6ccc1c1c2c3c4c5c61]

### Comparative Synthesis Example 3

First Step: Friedel-Craft Acylation Reaction

33.7 g (0.166 mol) of terephthaloylchloride, 77.3 g (0.333 mol) of methoxypyrene, and 330 g of 1,2-dichloroethane were put in a flask, preparing a solution. Subsequently, 44.4 g (0.333 mol) of aluminum chloride was slowly added to the solution at ambient temperature and heated to 60° C. for 8 hours. When a reaction was completed, methanol was added to the solution to form precipitates, and the precipitates were filtered to obtain double-substituted benzoyl pyrene.

Second Step: Reduction Reaction

29.2 g (0.0492 mol) of the double-substituted benzoyl pyrene obtained in the first step and 174 g of tetrahydrofuran were put in a flask, preparing a solution. 18.6 g (0.492 mol) of a sodium borohydride aqueous solution was slowly added to the solution and then, stirred at ambient temperature for 24 hours. When a reaction was completed, the resultant was neutralized to about pH 7 with a 10% hydrogen chloride solution and extracted with ethyl acetate, obtaining a compound represented by Chemical Formula 4.

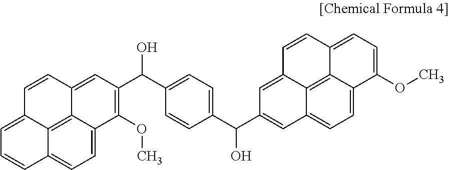 [SMILES: COc1ccc2ccc3cc(C(O)c4ccc(C(O)c5cc6ccc7cccc8ccc(c5OC)c6c78)cc4)cc4ccc1c2c34]

### SYNTHESIS EXAMPLES

### Synthesis Example 1

25 g (0.04 mol) of 4-((1-dihydrocoronen-1-yl)hydroxymethyl)phenol represented by Chemical Formula 2 according to Comparative Synthesis Example 1 and 125 g of N-methyl-2-pyrrolidone (NMP) were put in a flask, preparing a solution. 16.9 g (0.12 mol) of K₂CO₃ and 14.8 g (0.12 mol) of allyl bromide were slowly added to the solution and then, stirred at 70° C. for 24 hours. When a reaction was completed, the resultant was neutralized to about pH 7 with a 10% hydrogen chloride solution and extracted with ethyl acetate, obtaining a compound represented by Chemical Formula a. (Mw=698.8 g/mol)

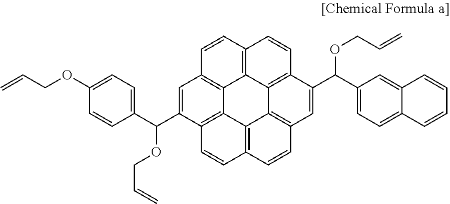 [SMILES: C=CCOc1ccc(C(OCC=C)c2cc3ccc4ccc5c(C(OCC=C)c6ccc7ccccc7c6)cc6ccc7ccc2c2c7c6c5c4c32)cc1]

### Synthesis Example 2

A compound represented by Chemical Formula b was obtained in the same manner as in Synthesis Example 1 except that 14.3 g (0.12 mol) of propargyl bromide was used instead of the allyl bromide. (Mw=692.8 g/mol)

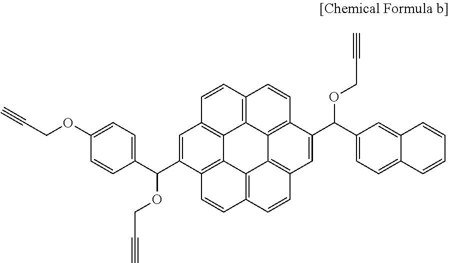 [SMILES: C#CCOc1ccc(C(OCC#C)c2cc3ccc4ccc5c(C(OCC#C)c6ccc7ccccc7c6)cc6ccc7ccc2c2c7c6c5c4c32)cc1]

### Synthesis Example 3

A compound represented by Chemical Formula c was obtained in the same manner as in Synthesis Example 1 except that 45.9 g (0.166 mol) of benzoperylene was used instead of 50.0 g (0.166 mol) of the coronene. (Mw=674.8 g/mol)

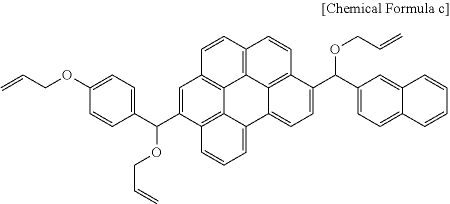 [SMILES: C=CCOc1ccc(C(OCC=C)c2cc3ccc4ccc5c(C(OCC=C)c6ccc7ccccc7c6)ccc6c7cccc2c7c3c4c56)cc1]

Preparation of Hardmask Compositions

### Example 1

2 g of the compound according to Synthesis Example 1 was dissolved in 10 g of a solvent prepared by mixing propylene glycol monomethyl ether acetate (PGMEA) and cyclohexanone in a mass ratio of 7:3 and then, filtered with a 0.1 μm TEFLON (tetrafluoroethylene) filter, preparing a hardmask composition.

### Example 2

A hardmask composition was prepared in the same manner as in Example 1 except that the compound of Synthesis Example 2 was used instead of the compound of Synthesis Example 1.

### Example 3

A hardmask composition was prepared in the same manner as in Example 1 except that the compound of Synthesis Example 3 was used instead of the compound of Synthesis Example 1.

### Comparative Example 1

A hardmask composition was prepared in the same manner as in Example 1 except that the compound of Comparative Synthesis Example 1 was used instead of the compound of Synthesis Example 1.

### Comparative Example 2

A hardmask composition was prepared in the same manner as in Example 1 except that the compound of Comparative Synthesis Example 2 was used instead of the compound of Synthesis Example 1.

### Comparative Example 3

A hardmask composition was prepared in the same manner as in Example 1 except that the compound of Comparative Synthesis Example 3 was used instead of the compound of Synthesis Example 1.

Evaluation 1: Solubility Evaluation

Each hardmask composition according to Examples 1 to 3 and Comparative Examples 1 to 3 was stored at a low temperature (3° C. or less) for 3 months and then, examined with respect to an amount of precipitates.

When a solid was not visually precipitated in a solution with naked eyes solubility was evaluated to be excellent.

When a solid was precipitated in a solution, 0 is given, and when not precipitated, X is given.

TABLE 1

| | Precipitated or not |
|---|---|
| Example 1 | X |
| Example 2 | X |
| Example 3 | X |
| Comparative Example 1 | ◯ |
| Comparative Example 2 | ◯ |
| Comparative Example 3 | X |

Referring to Table 1, Examples 1 to 3 exhibited good solubility, compared with Comparative Examples 1 and 2.

Evaluation 2: Evaluation of Etch Resistance

13 wt % of each hardmask composition according to Examples 1 to 3 and Comparative Examples 1 to 3 was spin-on coated on a silicon wafer, heat-treated at 300° C. for 2 minutes and then, at 500° C. to 600° C. for 2 minutes on a hot plate under a N₂ atmosphere, forming thin films. The thin films were measured with respect to a thickness by using a thin film thickness meter made by K-MAC. Subsequently, the thin films were dry etched by using N₂/O₂ mixed gas for 60 seconds and measured with respect a thickness, which was used to calculate an etch rate. A thickness difference of each organic film before and after the dry etching was used with etching time to calculate a bulk etch rate (BER) according to Calculation Equation 1. The calculation results are shown in Table 2.

[Calculation Equation 1]

Etch rate (Å/s)=(initial thin film thickness−thin film thickness after etching)/etch time (sec)

TABLE 2

| | | Thin film | |
|---|---|---|---|
| | Initial thin | thickness | |
| | film thickness | after etching | Etch rate |
| | (Å) | (Å) | (Å/s) |
| Example 1 | 4,596 | 1,468 | 28.1 |
| Example 2 | 4,209 | 1,968 | 29.2 |
| Example 3 | 4,737 | 2,186 | 28.5 |
| Comparative Example 1 | 3,769 | 2,279 | 30.1 |
| Comparative Example 2 | 4,840 | 2,257 | 31.5 |
| Comparative Example 3 | 4,530 | 1,942 | 35.1 |

Referring to Table 2, the thin films formed of the hardmask compositions according to Examples 1 to 3 exhibited lower etch rates, compared with those of the thin films formed of the hardmask compositions according to Comparative Example 1 to 3. Accordingly, the hardmask compositions according to Examples 1 to 3 exhibited high cross-linking degrees and thus high etch resistance, compared with the hardmask compositions according to Comparative Examples 1 to 3.

By way of summation and review, according to small-sizing the pattern to be formed, it may be difficult to provide a fine pattern having an excellent profile using some lithographic techniques. Accordingly, an auxiliary layer, called a hardmask layer, may be formed between the material layer and the photoresist layer to provide a fine pattern.

One or more embodiments may provide a hardmask composition that is effectively applicable to a hardmask layer.

The hardmask composition according to the embodiment may have excellent solubility in a solvent and thus may be effectively applied to the hardmask layer.

The hardmask layer formed from the hardmask composition according to the embodiment may help secure excellent etch resistance, chemical resistance, and heat resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a compound represented by Chemical Formula 1, and
a solvent, 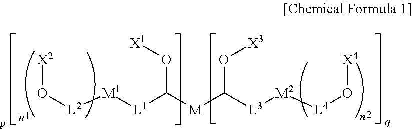
wherein, in Chemical Formula 1,
M includes a condensed ring structure including two or more benzene rings,
M¹ and M² are each independently a substituted or unsubstituted C6 to C20 aromatic hydrocarbon group,
X¹ to X⁴ are each independently hydrogen, a substituted or unsubstituted C1 to C30 saturated aliphatic hydrocarbon group, a substituted or unsubstituted C2 to C30 unsaturated aliphatic hydrocarbon group, a substituted or unsubstituted C3 to C30 saturated or unsaturated alicyclic hydrocarbon group, or a combination thereof, provided that at least one of X¹ to X⁴ is a substituted or unsubstituted C2 to C30 unsaturated aliphatic hydrocarbon group or a substituted or unsubstituted C3 to C30 unsaturated alicyclic hydrocarbon group,
L¹ to L⁴ are each independently a single bond, a substituted or unsubstituted divalent C1 to C30 saturated aliphatic hydrocarbon group, a substituted or unsubstituted divalent C2 to C30 unsaturated aliphatic hydrocarbon group, or a combination thereof,
n¹ and n² are each independently an integer greater than or equal to 0, provided that n¹ does not exceed a valence of M¹ and that n² does not exceed a valence of M², and
p and q are each independently an integer greater than or equal to 0, and p+q is greater than or equal to 1, provided that p+q does not exceed a valence of M.

2. The hardmask composition as claimed in claim 1, wherein M includes a condensed ring structure Group 1:

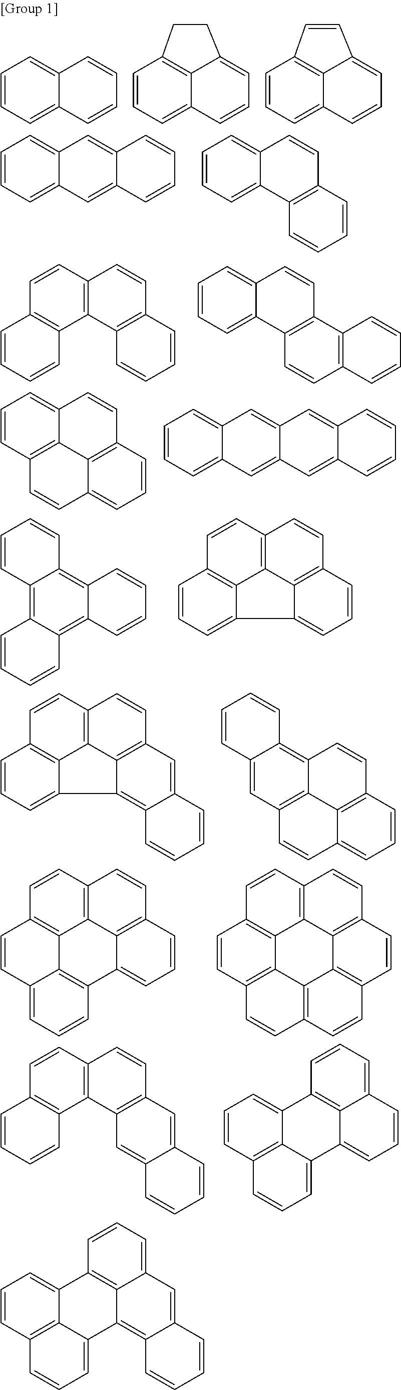

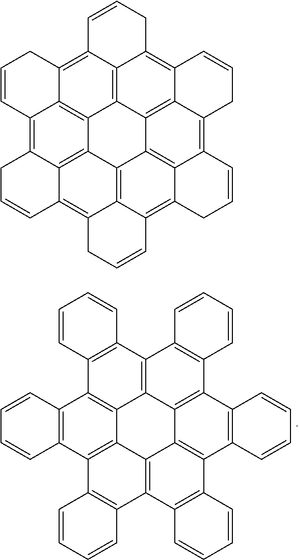

3. The hardmask composition as claimed in claim 1, wherein M¹ and M² each independently include a substituted or unsubstituted moiety of Group 2:

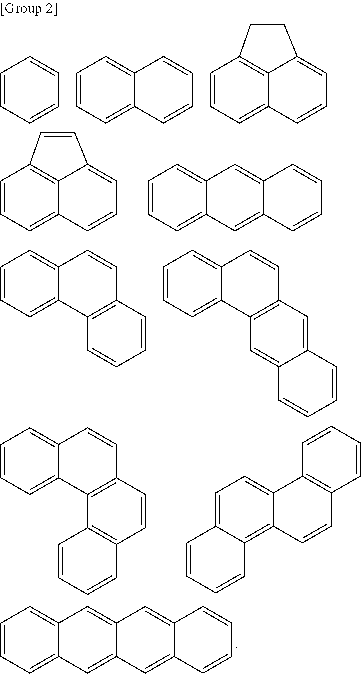

4. The hardmask composition as claimed in claim 1, wherein M includes a condensed ring structure of Group 1-1:

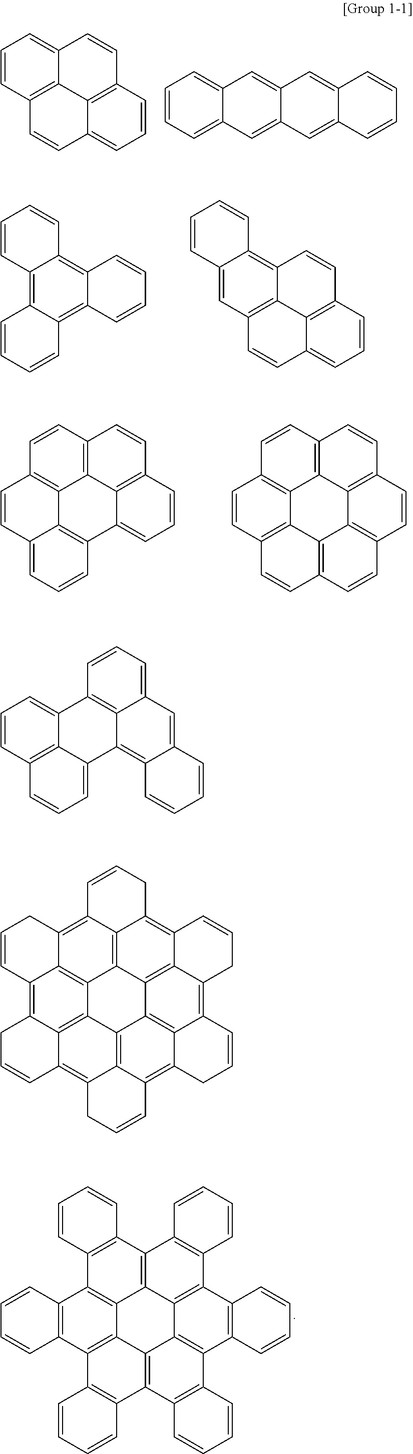

5. The hardmask composition as claimed in claim 1, wherein M includes a condensed ring structure of Group 1-2:

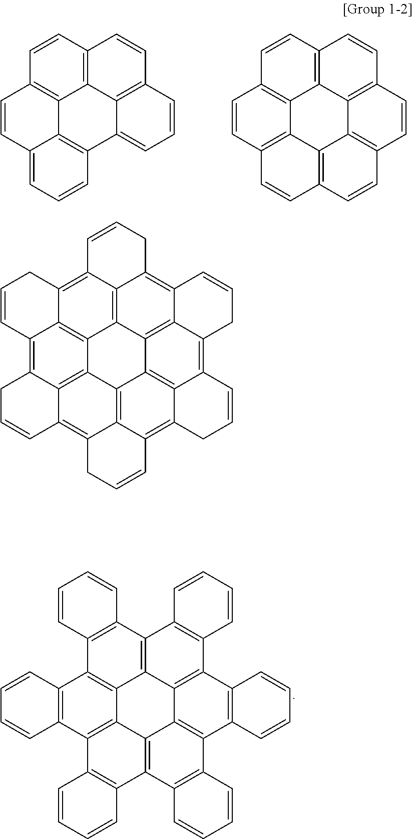

6. The hardmask composition as claimed in claim 1, wherein M¹ and M² are each independently a substituted or unsubstituted phenylene group or a substituted or unsubstituted naphthalenylene group.

7. The hardmask composition as claimed in claim 1, wherein X¹ to X⁴ are each independently hydrogen, a substituted or unsubstituted C1 to C20 alkyl group, a substituted or unsubstituted C2 to C20 alkenyl group, a substituted or unsubstituted C2 to C20 alkynyl group, or a combination thereof, provided that at least one of X¹ to X⁴ is a substituted or unsubstituted C2 to C10 alkenyl group or a substituted or unsubstituted C2 to C10 alkynyl group.

8. The hardmask composition as claimed in claim 1, wherein L¹ to L⁴ are each independently a single bond or a substituted or unsubstituted C1 to C10 alkylene group.

9. The hardmask composition as claimed in claim 1, wherein:
n¹ and n² are each independently an integer of 0 to 5, and
p and q are each independently 0 or 1, provided both p and q are not 0.

10. The hardmask composition as claimed in claim 1, wherein:
X¹ to X⁴ in Chemical Formula 1 are each independently hydrogen, a substituted or unsubstituted C1 to C10 alkyl group, a substituted or unsubstituted C2 to C10 alkenyl group, a substituted or unsubstituted C2 to C10 alkynyl group, or a combination thereof, provided that at least one of X¹ to X⁴ is a substituted or unsubstituted C2 to C6 alkenyl group or a substituted or unsubstituted C2 to C6 alkynyl group,
L¹ to L⁴ are each independently a single bond or a substituted or unsubstituted C1 to C10 alkylene group,
n¹ and n² are each independently an integer of 0 to 3, and
p and q are each 1.

11. The hardmask composition as claimed in claim 1, wherein the compound represented by Chemical Formula 1 is represented by one of Chemical Formula 1-A to Chemical Formula 1-K: 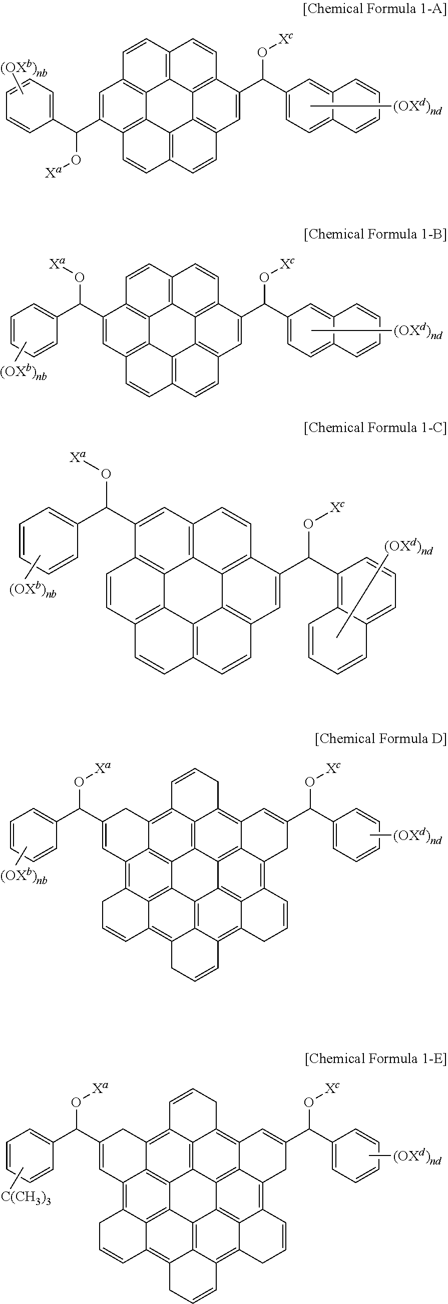 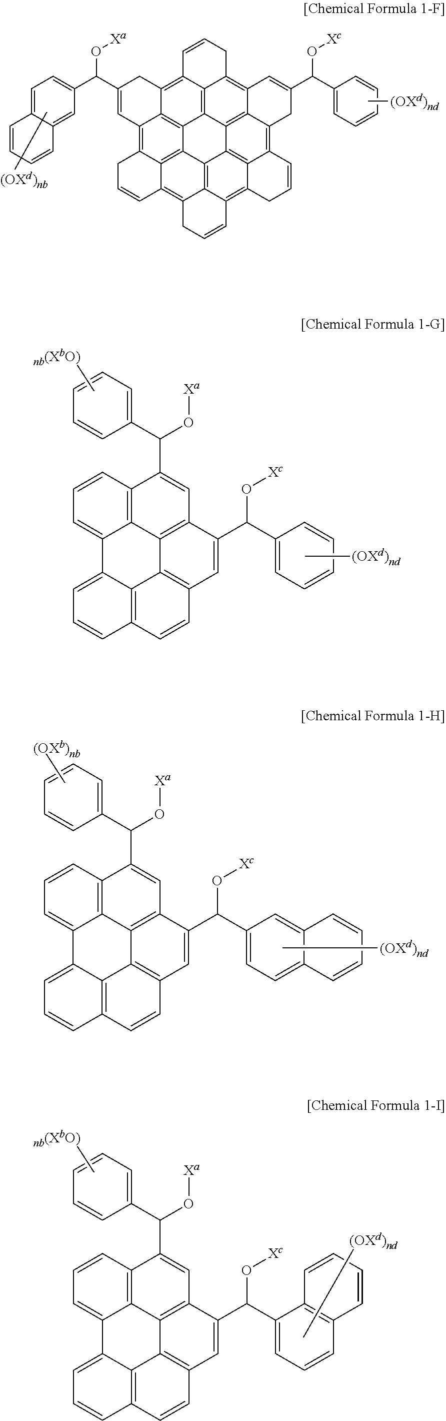 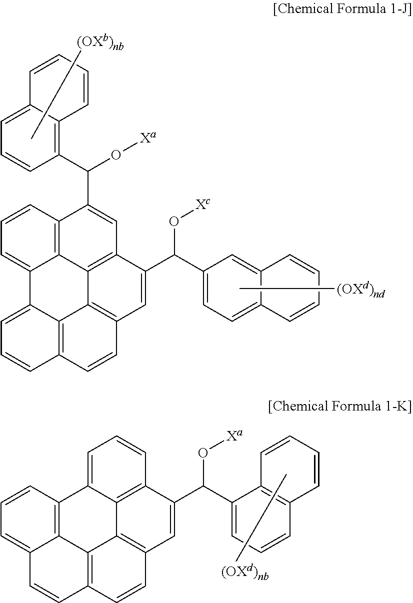
wherein, in Chemical Formula 1-A to Chemical Formula 1-K,
X^{a} to X^{d} are each independently hydrogen, a substituted or unsubstituted C1 to C20 alkyl group, a substituted or unsubstituted C2 to C20 alkenyl group, a substituted or unsubstituted C2 to C20 alkynyl group, or a combination thereof, provided that at least one of X^{a} to X^{d} are a substituted or unsubstituted C2 to C20 alkenyl group a substituted or unsubstituted C2 to C20 alkynyl group such that the compound represented by one of Chemical Formula 1-A to Chemical Formula 1-K includes at least one of a substituted or unsubstituted C2 to C10 alkenyl group or a substituted or unsubstituted C2 to C10 alkynyl group,
nb and nd are each independently an integer of 0 to 3, and
when both nb and nd are 0, at least one of X^{a} and X^{c} is not hydrogen.

12. The hardmask composition as claimed in claim 1, wherein the compound represented by Chemical Formula 1 is represented by one of Chemical Formula a to Chemical Formula c:

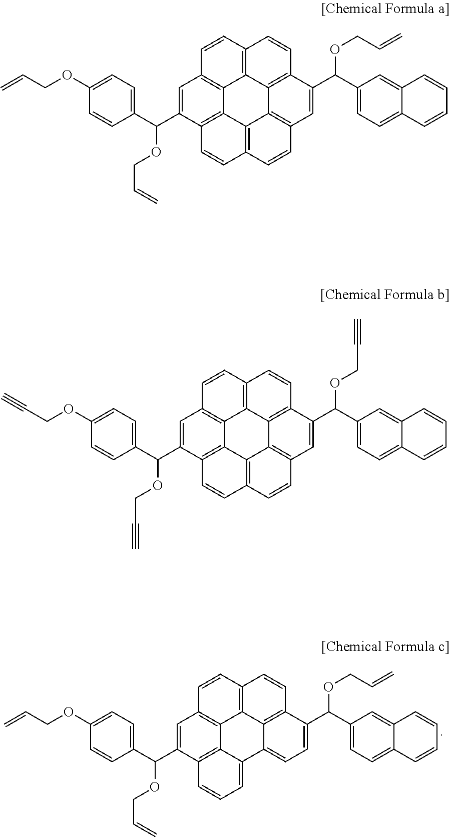 [SMILES: C=CCOc1ccc(C(OCC=C)c2cc3ccc4ccc5c(C(OCC=C)c6ccc7ccccc7c6)cc6ccc7ccc2c2c7c6c5c4c32)cc1 ; C#CCOc1ccc(C(OCC#C)c2cc3ccc4ccc5c(C(OCC#C)c6ccc7ccccc7c6)cc6ccc7ccc2c2c7c6c5c4c32)cc1 ; C=CCOc1ccc(C(OCC=C)c2cc3ccc4ccc5c(C(OCC=C)c6ccc7ccccc7c6)ccc6c7cccc2c7c3c4c56)cc1]

13. The hardmask composition as claimed in claim 1, wherein a molecular weight of the compound represented by Chemical Formula 1 is about 200 g/mol to about 3,000 g/mol.

14. The hardmask composition as claimed in claim 1, wherein the hardmask composition includes the compound represented by Chemical Formula 1 in an amount of about 0.1 wt % to about 30 wt %, based on a total weight of the hardmask composition.

15. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

16. A hardmask layer comprising a cured product of the hardmask composition as claimed in claim 1.

17. A method of forming patterns, the method comprising:
providing a material layer on a substrate,
applying the hardmask composition as claimed in claim 1 on the material layer,
heat-treating the hardmask composition to form a hardmask layer,
forming a photoresist layer on the hardmask layer,
exposing and developing the photoresist layer to form a photoresist pattern,
selectively removing the hardmask layer using the photoresist pattern to expose a portion of the material layer, and
etching an exposed portion of the material layer.

18. The method as claimed in claim 17, wherein heat-treating the hardmask composition is performed at about 100° C. to about 1,000° C.
